(19) United States
(12) Patent Application Publication
(10) Pub. No.: US 2024/0353761 A1
(43) Pub. Date: Oct. 24, 2024

(54) METROLOGY SYSTEM, LITHOGRAPHIC APPARATUS, AND METHOD

(71) Applicant: ASML Netherlands B.V., Veldhoven (NL)

(72) Inventors: Sebastianus Adrianus GOORDEN, Eindhoven (NL); Simon Reinald HUISMAN, Eindhoven (NL); Filippo ALPEGGIANI, Waalre (NL)

(73) Assignee: ASML Netherlands B.V., Veldhoven (NL)

(21) Appl. No.: 18/686,742

(22) PCT Filed: Aug. 5, 2022
(86) PCT No.: PCT/EP2022/072151

§ 371 Date: Feb. 26, 2024

Related U.S. Application Data
(60) Provisional application No. 63/238,478, filed on Aug. 30, 2021.

(51) Int. Cl. G03F 7/00; G03F 9/00

(52) U.S. Cl. CPC G03F 7/70633; G03F 7/70408; G03F 9/7092

(57) ABSTRACT

Systems, apparatuses, and methods are provided for correcting an alignment measurement or overlay error. An example method can include measuring an observable in response to an illumination of a region of a surface by a radiation beam, such as interference between radiation diffracted from the region. The example method can further include generating a measurement signal indicative of the observable. In some aspects, the measurement signal can include interference fringe pattern data indicative of the measured interference. The example method can further include determining a correction to a measurement value based on measurement signal. Optionally, the correction can include a correction to an alignment measurement of an alignment sensor, a correction to an overlay error of an overlay sensor, or both.

### CROSS-REFERENCE TO RELATED APPLICATIONS

This application claims priority of U.S. Provisional Patent Application No. 63/238,478, which was filed on Aug. 30, 2021, and which is incorporated herein in its entirety by reference.

### TECHNICAL FIELD

The present disclosure relates to metrology systems that may be used, for example, in a lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Extreme ultraviolet (EUV) radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

During lithographic operation, different processing steps may require different layers to be sequentially formed on the substrate. Accordingly, it may be necessary to position the substrate relative to prior patterns formed thereon with a high degree of accuracy. Generally, alignment marks are placed on the substrate to be aligned and are located with reference to a second object. A lithographic apparatus may use a metrology system for detecting positions (e.g., X and Y positions) of the alignment marks and for aligning the substrate using the alignment marks to ensure accurate exposure from a mask. However, any level variation or asymmetry present in the alignment marks can make it challenging to accurately align the substrate.

### SUMMARY

The present disclosure describes various aspects of systems, apparatuses, and methods for determining a correction to a measurement value based on interference fringe pattern data (e.g., microscope images of bright-field microscope systems, dark-field microscope systems, or both, especially when the target contains periodic structures), such as a correction to an alignment measurement of an alignment sensor, a correction to an overlay error of an overlay sensor, any other suitable correction or modification, or any combination thereof. In some aspects, the correction can correct for layer thickness variations for camera-based metrology sensors.

In some aspects, the present disclosure describes a metrology system. The metrology system can include an illumination system configured to generate a radiation beam and direct the radiation beam toward a region of a surface of a substrate. As used herein, the term “substrate” can refer to any material layer in a semiconductor stack. The metrology system can further include a detection system configured to measure an interference between radiation diffracted from the region in response to an illumination of the region by the radiation beam. The detection system can be further configured to generate a measurement signal comprising interference fringe pattern data indicative of the measured interference. The metrology system can further include a controller configured to determine a correction to a measurement value based on the interference fringe pattern data.

In some aspects, the present disclosure describes a lithographic apparatus. The lithographic apparatus can include a radiation source configured to illuminate a pattern of a patterning device. The lithographic apparatus can further include a projection system configured to project an image of the pattern onto a target portion of a substrate. The lithographic apparatus can further include a metrology system. The metrology system can include an illumination system configured to generate a radiation beam and direct the radiation beam toward a region of a surface of a substrate. The metrology system can further include a detection system configured to measure an interference between radiation diffracted from the region in response to an illumination of the region by the radiation beam. The detection system can be further configured to generate a measurement signal comprising interference fringe pattern data indicative of the measured interference. The metrology system can further include a controller configured to determine a correction to a measurement value based on the interference fringe pattern data.

In some aspects, the present disclosure describes a method for correcting an alignment measurement or overlay error. The method can include measuring, by an imaging device and at an image plane of the imaging device, an interference between radiation diffracted from the region in response to an illumination of the region by the radiation beam. The method can further include generating, by a controller, a measurement signal comprising interference fringe pattern data indicative of the measured interference. The method can further include determining, by the controller, a correction to a measurement value based on the interference fringe pattern data.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of an example metrology system according to some aspects of the present disclosure.

FIG. 5 is a schematic illustration of another example metrology system according to some aspects of the present disclosure.

FIG. 6 shows visualizations of an example measurement signal that includes interference fringe pattern data according to some aspects of the present disclosure.

FIGS. 7A-7B are schematic illustrations of metrology system according to some aspects of the present disclosure.

FIG. 8 shows visualizations of another example measurement signal that includes interference fringe pattern data according to some aspects of the present disclosure.

FIG. 9 shows visualizations of example interference fringe pattern data and an example position map generated therefrom according to some aspects of the present disclosure.

FIG. 10 is a graphical representation of example measurement signals resulting from layer thickness variation according to some aspects of the present disclosure.

FIG. 11 is an example method for correcting an alignment measurement or overlay error according to some aspects of the present disclosure or portion(s) thereof.

FIG. 12 is an example computer system for implementing some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

In one example, some alignment and overlay techniques may be substantially incapable of removing unwanted effects due to level variations, mark asymmetry, and other such particulars. Additionally, the performance of many alignment and overlay sensors can be impacted by process-dependence in combination with imperfect optics. For instance, a stack change can change the distribution of light in the pupil of the sensor, the light can probe a different part of the (imperfect) optics, and can see a different attenuation or phase aberration, which can lead to a different overlay or aligned position measurement value. Some alignment techniques can use pupil metrology to correct for layer thickness variations for camera-based metrology sensors, such as the techniques described in European Patent Application No. 20170482.2, filed Apr. 20, 2020, and titled “ALIGNMENT METHOD AND ASSOCIATED ALIGNMENT AND LITHOGRAPHIC APPARATUSES,” which is hereby incorporated by reference in its entirety.

In contrast, some aspects of the present disclosure can provide for using a detected change in the period and/or orientation of the interference fringe pattern on the field camera, instead of an observable in the pupil plane, to correct for the measurement errors resulting from the coupled effects of a wide distribution of angles of incidence, sensor aberration, and stack thickness variation, or to correct for tool induced shift (TIS).

In some aspects, the present disclosure provides for correcting an alignment measurement or overlay error. For example, the present disclosure provides for measuring an interference between radiation diffracted from the region in response to an illumination of the region by the radiation beam. In some aspects, the illumination radiation can be fully coherent, spatially incoherent, or spatially partially coherent, or in general can have any spatial coherence profile. The present disclosure further provides for generating a measurement signal comprising interference fringe pattern data indicative of the measured interference. The present disclosure further provides for determining a correction to a measurement value based on the interference fringe pattern data. As described herein, the correction can include a correction to an alignment measurement of an alignment sensor, a correction to an overlay error of an overlay sensor, any other suitable correction, or any combination thereof.

In some aspects, the present disclosure provides for correcting an aligned position based on the phase difference between, for example, the positive and negative first diffraction orders. In some aspects, the present disclosure provides for correcting an initial alignment position measurement by solving the equation “Aligned_position_corrected=aligned_position_raw+correction_coefficient*observable_on_field_camera,” where the parameter “observable_on_field_camera” can be indicative of, for example, the change in the period and/or orientation of the fringe pattern.

In some aspects, instead of using the average behavior (e.g., fringe period or apparent position deviation (APD) gradient) over the whole mark as an observable. the present disclosure provides for using higher order behavior (e.g. fringe curvature or higher order APD mark shapes) as observables to correct for the measurement errors resulting from the coupled effects of a wide distribution of angles of incidence, sensor aberration, and stack thickness variation. In some aspects where multiple higher-order observables are used, the present disclosure provides for correcting an initial alignment position measurement by solving the example equation “Aligned_position_corrected=aligned_position_raw+SUM_i{correction_coefficient_i*observable_on_field_camera_i}.” This example equation is a linear model but there can also be quadratic and higher order polynomial terms and cross-terms. Additionally, the example equation may not be polynomial but in general any model having any relation between observable and correction can be used, including machine learning types of models.

In some aspects, the present disclosure further provides for utilizing these observables to correct for other effects such as wavelength-induced errors, defocus, impact of surrounding structures, and other such effects.

In some aspects, the present disclosure provides for dark-field measurement modes (e.g., interfering positive and negative first, second, and/or higher diffraction orders), as well as for bright-field measurement modes (e.g., interfering first and zeroth diffraction orders).

In some aspects, the present disclosure provides for correcting an overlay error (e.g., based on the intensity difference between the positive and negative first diffraction orders) in any overlay sensor that uses an interference pattern on a camera. One exemplary aspect is that the overlay error correction techniques disclosed herein can be performed for every mark on every wafer without throughput loss (e.g., as opposed to a rotated wafer measurement).

In some aspects, the present disclosure provides for correcting an overlay error in any overlay sensor that uses an interference pattern on a camera. This includes image-based overlay sensors, sensors that use a continuous bias diffraction-based overlay (cDBO) or robust advanced imaging mode (rAIM®) measurement principle, and sensors that are based on digital holographic microscopy (e.g., using an off-axis reference beam). In addition, the present disclosure provides for correcting an overlay error in sensors that do not use an interference pattern in their primary measurement mode, such as Yieldstar microDBO. A first technique determines an observable on the field camera such as an intensity gradient or higher order term. A second technique determines an observable on a derived image, such as on an intensity imbalance image. A third technique determines an observable on other derived quantities, such as the A+/A− curve (e.g., combining measurements of multiple colors). In this third technique, the observable can be spatially averaged over the mark, or it can be spatially resolved. A fourth technique adds a second measurement mode in which an interference pattern is created. In this fourth technique, an observable from the second measurement mode can be used to correct for an overlay error determined in the first measurement mode.

In some aspects, the present disclosure provides for correcting an initial overlay measurement by extracting one or more observables from the field camera signal and by using a model where the overlay correction is a function of the observables, such as a linear combination of the observables with multiplicative coefficients or any other linear or non-linear model. In one example, the present disclosure can provide for correcting an initial overlay measurement by solving the equation “Overlay_corrected=overlay_raw+correction_coefficient*observable_on_field_camera,” where the parameter “observable_on_field_camera” can be, for example, a change in period of the interference pattern. In some aspects, the parameter “correction_coefficient” can be calibrated (i) with a rotated wafer measurement, and/or (ii) with after etch inspection (AEI) metrology and scanning electron microscopy (SEM) feedback, and/or (iii) with design for control (D4C) simulated data, which may be combined with modeled or measured sensor aberration data, and/or (iv) by comparing overlay data measured on multiple nearby marks with, for example, different pitches and/or subsegmentations, and/or (v) by comparing through-color data (e.g., when many colors are measured in a calibration phase and fewer colors are measured in a high-volume phase to increase throughput).

In some aspects, the present disclosure provides for calibrating the “correction_coefficient” parameter described herein in various ways, such as by measuring the optical aberration profile of the sensor or using after development inspection (ADI), AEI, or SEM feedback data. In some aspects, such calibrations may also benefit from D4C simulated data, by comparing alignment data measured on multiple nearby marks with, for example, different pitches and/or subsegmentations, or by comparing through-color data (e.g., assuming smoothness of the optical aberration profile). Additionally or alternatively, variations within a wafer can be used to calibrate one or more “correction_coefficient” parameters. For example, the correction_coefficient(s) can be optimized to minimize the variation of the alignment or overlay wafer grid or wafer grid residuals. In another example, the “correction_coefficient(s)” can be optimized to minimize certain grid shapes or certain model parameters. For instance, when the stack parameter (e.g., layer thickness) that leads to measurement errors is known or suspected to vary radially over the wafer, then the “correction_coefficient(s)” can be optimized to minimize some or all radial basis function contributions in the “aligned_position_corrected” or “overlay_corrected” wafer grids. An example implementation can be to combine this technique with Wafer Alignment Model Mapping (WAMM) or TOP-align methods.

There are many exemplary aspects to the systems, apparatuses, methods, and computer program products disclosed herein. For example, aspects of the present disclosure provide for decreasing the impact of layer thickness variation (or other stack variations) in combination with optical aberrations in order to enable accurate alignment on small marks. In another example, aspects of the present disclosure provide for improved overlay by improving throughput, accuracy, or both. In yet another example, aspects of the present disclosure provide for improved alignment by improving accuracy in the presence of wafer-to-wafer process variation combined with a lower cost and miniaturizable, parallelizable system, enabling the roadmap to measure many more alignment marks.

Before describing such aspects in more detail, however, it is instructive to present an example environment in which aspects of the present disclosure can be implemented.

### Example Lithographic Systems

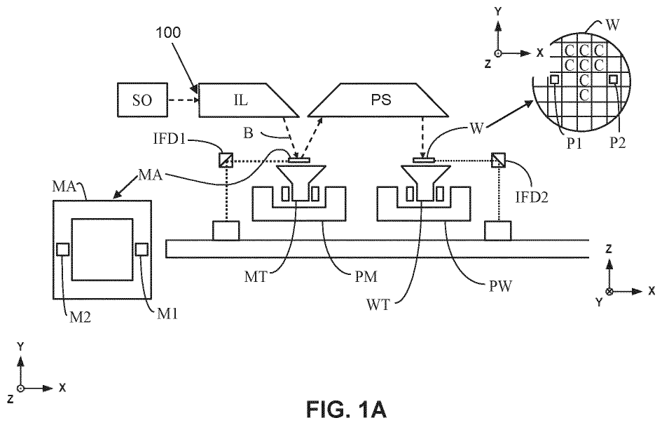

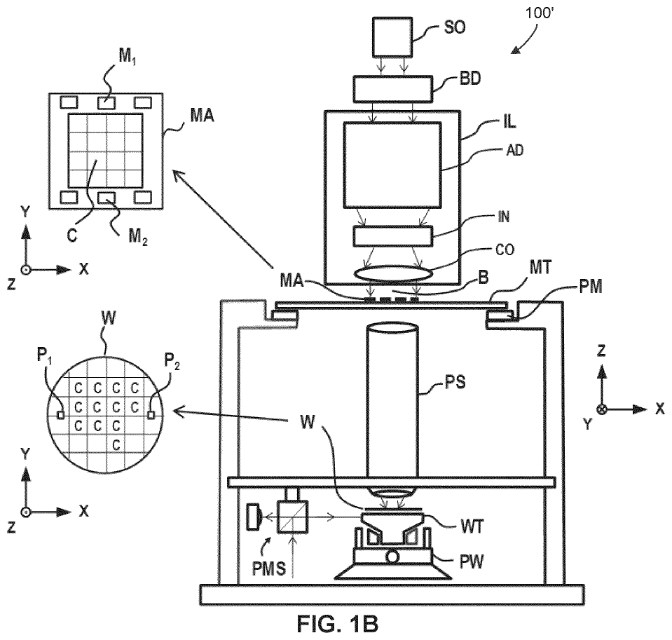

FIGS. 1A and 1B are schematic illustrations of a lithographic apparatus 100 and a lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a deep ultra violet (DUV) radiation beam or an extreme ultra violet (EUV) radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100′ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IFD2 (e.g., an interferometric device, linear encoder, or capacitive sensor), the substrate table WT can be moved accurately, e.g., so as to position different target portions C in the path of the radiation beam B. Similarly, the first positioner PM and another position sensor IFD1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are known as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system pupil. In some aspects, portions of radiation can emanate from the intensity distribution at the illumination system pupil and traverse a mask pattern without being affected by diffraction at the mask pattern MP and create an image of the intensity distribution at the illumination system pupil.

The projection system PS projects an image MP′ of the mask pattern MP, where image MP′ is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Reflected light (e.g., zeroth-order diffracted beams) traverses the pattern without any change in propagation direction. The zeroth-order diffracted beams traverse an upper lens or upper lens group of the projection system PS, upstream of the pupil conjugate of the projection system PS, to reach the pupil conjugate. The portion of the intensity distribution in the plane of the pupil conjugate and associated with the zeroth-order diffracted beams is an image of the intensity distribution in the illumination system pupil of the illumination system IL. In some aspects, an aperture device can be disposed at, or substantially at, a plane that includes the pupil conjugate of the projection system PS.

The projection system PS is arranged to capture, by means of a lens or lens group, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of an illumination system pupil. Further, in some aspects, astigmatism aberration can be reduced by blocking the zeroth-order beams in the pupil conjugate of the projection system PS associated with radiation poles in opposite quadrants. This is described in more detail in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position measurement system PMS (e.g., including a position sensor such as an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:

1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.

2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-) magnification and image reversal characteristics of the projection system PS.

3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV source configured to generate an EUV radiation beam B for EUV lithography. In general, the EUV source can be configured in a radiation source SO, and a corresponding illumination system IL can be configured to condition the EUV radiation beam B of the EUV source.

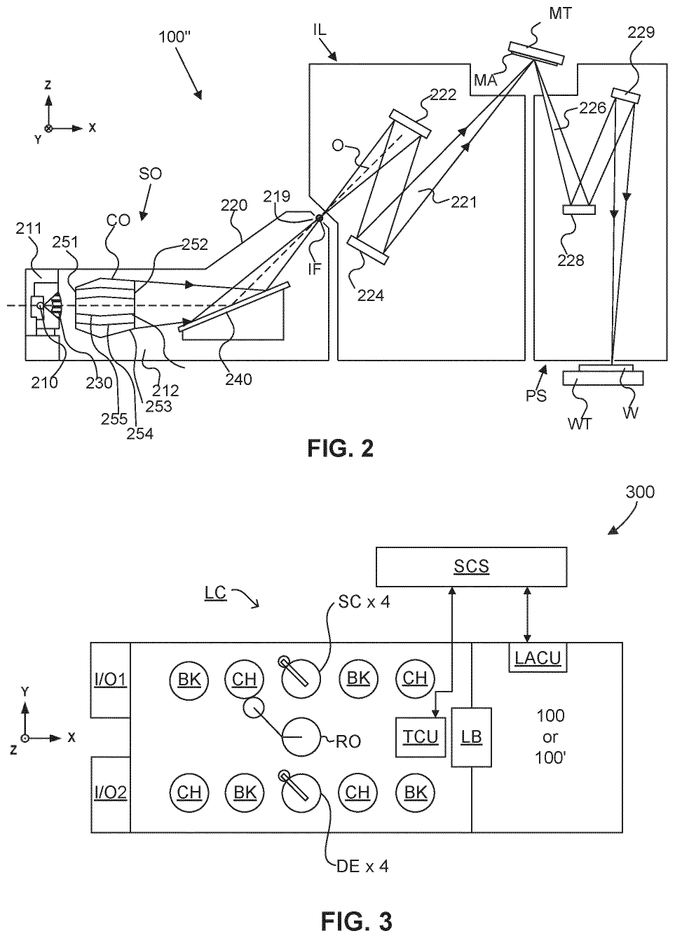

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in the source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. The grating spectral filter 240 can be used to suppress infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

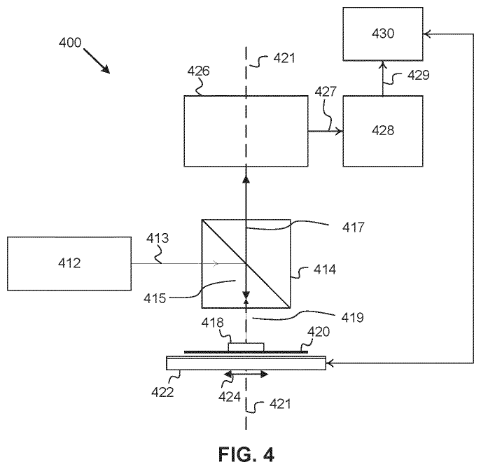

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Metrology Systems

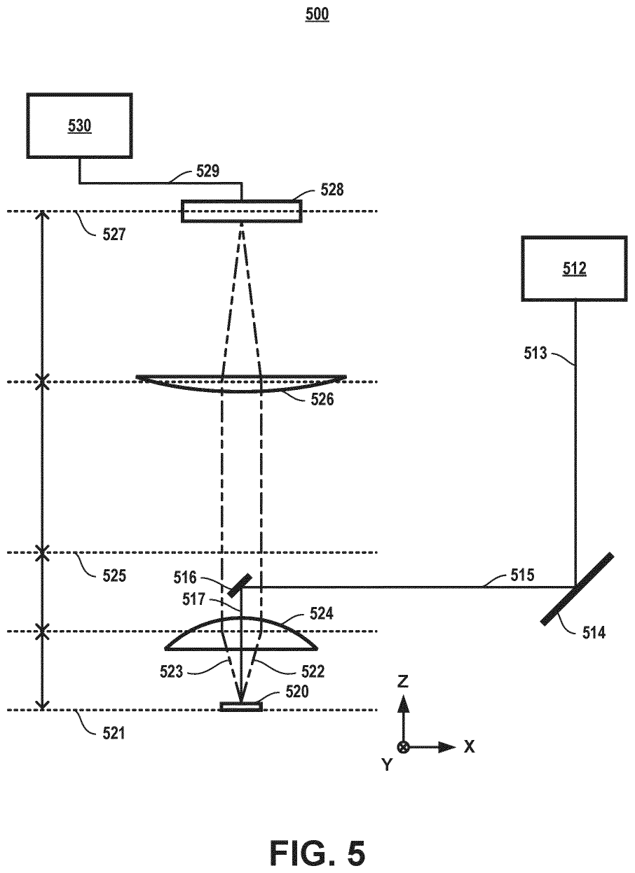

FIG. 4 illustrates a schematic of a cross-sectional view of a metrology system 400 that can be implemented as a part of lithographic apparatus 100 or 100′, according to an embodiment. In an example of this embodiment, metrology system 400 may be configured to align a substrate (e.g., substrate W) with respect to a patterning device (e.g., patterning device MA). Metrology system 400 may be further configured to detect positions of alignment marks on the substrate and to align the substrate with respect to the patterning device or other components of lithography apparatus 100 or 100′ using the detected positions of the alignment marks. Such alignment of the substrate may ensure accurate exposure of one or more patterns on the substrate.

According to an embodiment, metrology system 400 may include an illumination system 412, a reflector 414 (or, additionally or alternatively, a grating structure such as a lensing grating), an interferometer 426, a detector 428 (e.g., a balanced photodetector), and a controller 430, according an example of this embodiment. Illumination system 412 may be configured to provide a radiation beam 413. Radiation beam 413 may include, for example, an electromagnetic narrow band having one or more passbands. In another example, the one or more passbands may be discrete narrow passbands within a spectrum of wavelengths between about 350 nm to about 900 nm. Illumination system 412 may be further configured to provide one or more passbands having substantially constant center wavelength (CWL) values over a long period of time (e.g., over a lifetime of illumination system 412). Such configuration of illumination system 412 may help to prevent the shift of the actual CWL values from the desired CWL values, as discussed above, in current metrology systems. And, as a result, the use of constant CWL values may increase long-term stability and accuracy of metrology systems (e.g., metrology system 400) compared to the current metrology systems.

Reflector 414 may be configured to receive radiation beam 413 and direct radiation beam 413 towards substrate 420 as radiation beam 415, according an embodiment. Reflector 414 may be a mirror or dichromatic mirror. In one example, stage 422 is moveable along direction 424. Radiation beam 415 may be configured to illuminate a plurality of alignment marks 418 or targets located on substrate 420. In another example, radiation beam 415 is configured to reflect from a surface of substrate 420. The plurality of alignment marks 418 may be coated with a radiation sensitive film in an example of this embodiment. In another example, the plurality of alignment marks 418 may have one hundred and eighty degree symmetry. That is, when one alignment mark in the plurality of alignment marks 418 is rotated one hundred and eighty degrees about an axis of symmetry perpendicular to a plane of another alignment mark in the plurality of alignment marks 418, the rotated alignment mark may be substantially identical to the un-rotated alignment mark.

As illustrated in FIG. 4, interferometer 426 may be configured to receive radiation beam 417. A radiation beam 419 may be diffracted from the plurality of alignment marks 418, or reflected from a surface of substrate 420, and is received at interferometer 426 as radiation beam 417. Interferometer 426 can include any appropriate set of optical and/or electro-optical elements, for example, a combination of prisms that may be configured to form two images of the plurality of alignment marks 418 based on the received radiation beam 417. It should be appreciated that a good quality image need not be formed, but that the features of the plurality of alignment marks 418 should be resolved. Interferometer 426 may be further configured to rotate one of the two images with respect to the other of the two images one hundred and eighty degrees and recombine the two images interferometrically.

In an embodiment, detector 428 may be configured to receive the recombined image and detect an interference as a result of the recombined image when alignment axis 421 of metrology system 400 passes through a center of symmetry (not shown) of the plurality of alignment marks 418. Such interference may be due to the plurality of alignment marks 418 being one hundred and eighty degree symmetrical, and the recombined image interfering constructively or destructively, according to an example embodiment. Based on the detected interference, detector 428 may be further configured to determine a position of the center of symmetry of the plurality of alignment marks 418 and consequently, detect a position of substrate 420. According to an example, alignment axis 421 may be aligned with an optical beam perpendicular to substrate 420 and passing through a center of image rotation interferometer 426. In another example, detector 428 is configured to receive the recombined image and detect an interference of light being reflected off a surface of substrate 420.

In a further embodiment, controller 430 may be configured to receive a measurement signal 429 including measurement data. Measurement data can include, but is not limited to, electronic information indicative of the determined center of symmetry, interference fringe pattern data indicative of the measured interference, any other suitable information, or any combination thereof. Controller 430 may be further configured to determine a position of stage 422 and correlate the position of stage 422 with the position of the center of symmetry of the plurality of alignment marks 418. As such, the positions of the plurality of alignment marks 418 and consequently, the position of substrate 420 may be accurately determined with reference to stage 422. Alternatively, controller 430 may be configured to determine a position of metrology system 400 or any other reference element such that the center of symmetry of the plurality of alignment marks 418 may be determined with reference to metrology system 400 or any other reference element.

In an embodiment, controller 430 is configured to apply a correction to a measurement received from detector 428 to account for asymmetry that can exist in the plurality of alignment marks 418. The asymmetry can exist due to imperfections in the structure of the mark itself (e.g., sidewall angle, critical dimension spacing, etc.) or due to non-linear optical effects based on the wavelength of light being directed towards the plurality of alignment marks 418.

It should be noted that even though reflector 414 is shown to direct radiation beam 413 towards the plurality of alignment marks 418 as radiation beam 415, the disclosure is not so limiting. It would be apparent to a person skilled in the relevant art that other optical arrangements may be used to obtain the similar result of illuminating the plurality of alignment marks 418 on substrate 420 and detecting an image of the plurality of alignment marks 418. Reflector 414 may direct the illumination in a direction normal to the surface of substrate 420, or at an angle.

In some aspects, controller 430 can be configured to provide for (Smart) Mark Alignment Model Mapping ((S)MAMM). Because process effects such as grating asymmetry (e.g., local grating asymmetry) and layer thickness variation can show up in mark shape (e.g., local aligned position), controller 430 can be configured to implement(S)MAMM to monitor the mark shape from wafer to wafer and utilize this information to: (i) identify, quantify, and substantially eliminate different process effects than can impact accuracy; (ii) feed it forward to the alignment grid calculation (e.g., process robustness with only one color); (iii) correlate it to processing tools as a monitor; and/or (iv) feed it forward to improve overlay measurements (e.g., bottom grating information). In one illustrative and non-limiting example embodiments, controller 430 can be configured to utilize(S)MAMM to measure the mark shapes on multiple wafers. Controller 430 can be configured to identify a nominal mark shape (e.g., on a first wafer) and utilize that nominal mark shape for exposure correction. Controller 430 can be further configured to identify mark shapes (e.g., on second, third, and fourth wafers, etc.) caused by processing effects (e.g., grating asymmetry, layer thickness, etc.) and either not use these mark shapes for exposure correction or use these mark shapes to correct for process effects.

In some aspects, the mark shape or local aligned position is, or can be, related to the local interference fringe phase, period, and orientation. In some aspects, for overlay sensors that do not use interference fringe patterns (e.g., Yieldstar microDBO), the “mark shape” can be related to the intensity pattern measured on the camera (e.g., the intensity gradient and/or higher order terms). In some aspects, the “mark shape” can also be determined based on a derived quantity, such as an intensity imbalance image.

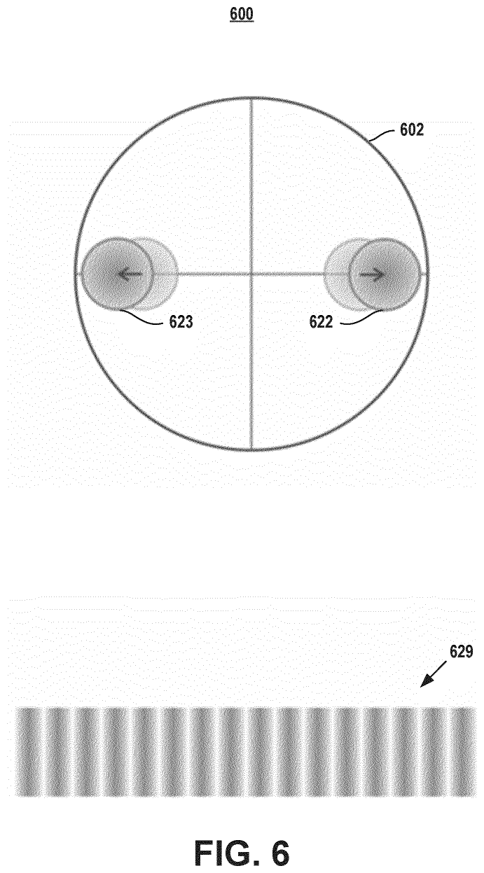

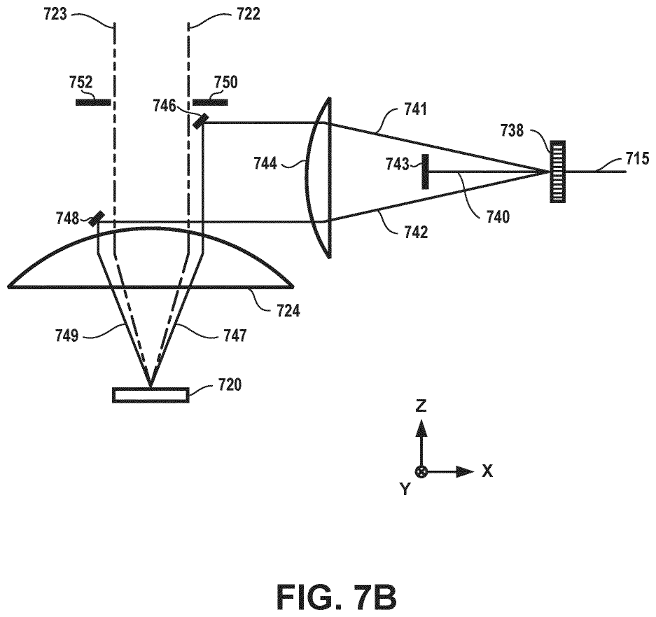

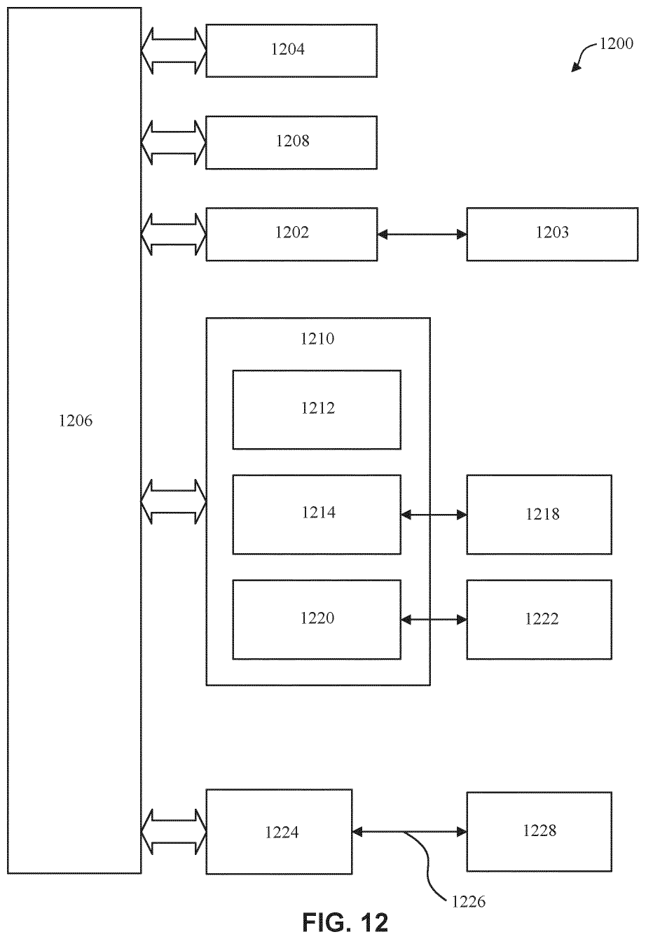

FIG. 5 is a schematic illustration showing a side view of a metrology system 500 according to some aspects of the present disclosure. In some aspects, the metrology system 500, or any portion thereof, can be implemented using any of the structures, components, features, or techniques described with reference to the metrology system 400 described with reference to FIG. 4; the metrology system 700 described with reference to FIG. 7; the example computing system 1200 described with reference to FIG. 12; any of the systems, structures, components, features, or techniques described in European Patent Application No. 20170482.2, filed Apr. 20, 2020, and titled “ALIGNMENT METHOD AND ASSOCIATED ALIGNMENT AND LITHOGRAPHIC APPARATUSES,” which is hereby incorporated by reference in its entirety; any other suitable structure, component, feature, or technique; any portion thereof; or any combination thereof.

As shown in FIG. 5, metrology system 500 can include an illumination system 512 (e.g., a light source) configured to generate a radiation beam 513 and direct radiation beam 513 toward a region of a surface of a substrate 520 that includes, in some aspects, a plurality of alignment marks. For example, metrology system 500 can further include a reflector 514 (e.g., a fold mirror) and a reflector 516. Illumination system 512 can transmit radiation beam 513 toward reflector 514. Reflector 514 can receive radiation beam 513 from illumination system 512 and direct the received radiation toward reflector 516 as radiation beam 515. Reflector 516 can receive radiation beam 515 from reflector 514 and direct the received radiation toward substrate 520 as radiation beam 517.

In some aspects, radiation diffracted from the region of the surface of substrate 520 in response to an illumination of the region by radiation beam 517 can include positive first order diffraction 522 and negative first order diffraction 523. Positive first order diffraction 522 and negative first order diffraction 523 can propagate through a lens 524 (e.g., an objective lens) and a lens 526 to an imaging device 728 (e.g., a camera) included in a detection system. Substrate 520 can be disposed at an object plane 521, imaging device 528 can be disposed at an image plane 527, and a pupil plane 525 can be disposed between object plane 521 and image plane 527.

The detection system can be configured to measure (e.g., by imaging device 528 at image plane 527) an interference between the radiation diffracted from the region of the surface of substrate 520 in response to the illumination of the region by radiation beam 517 and generate a measurement signal 529 that includes interference fringe pattern data indicative of the measured interference.

Metrology system 500 can further include a controller 530 configured to receive measurement signal 529 from imaging device 528 and determine a correction to a measurement value based on the interference fringe pattern data included in measurement signal 529. The correction can include, for example, a correction to an alignment measurement of an alignment sensor, a correction to an overlay error of an overlay sensor, any other suitable correction or modification, and any combination thereof. In some aspects, controller 530 can be configured to utilize the correction to improve measurement performance on smaller mark types by, for example, increasing intra-field wafer alignment, performing wafer edge correction, reducing scribe lane width, reducing process impact on a surrounding product, achieving any other suitable improvement, or any combination thereof.

In some aspects, controller 530 can be configured to correct for symmetric variations (e.g., layer thicknesses or linewidth) in the alignment marks. Additionally or alternatively, in some aspects, controller 530 can be configured to correct for asymmetric variations (e.g., grating asymmetry, spatially varying layer thickness variation, spatially varying linewidth, surrounding structure variation, etc.) in the alignment marks and/or aberration profiles in the sensor. In some aspects, the disclosed embodiments may correct for symmetric and/or asymmetric variations in the alignment marks in cases where a symmetric variation in the mark combined with an asymmetric variation in the sensor or an off-axis mark position with respect to the sensor leads to an alignment error.

In some aspects, controller 530 can be configured to determine a measurement value or correction therefor using at least one “observable” derived from the interference pattern measurement and at least one corresponding sensor or correction term relating to sensor optics used to perform said measurement. Observables can include, for example, periodicity, orientation, amplitude of interference fringes, background intensity level, intensity profile (e.g., even if there is no interference fringe), higher order terms, and combinations thereof. For example, controller 530 can be further configured to determine a change in a periodicity value of the interference fringe pattern data and determine the correction to the measurement value based on the change in the periodicity value. In another example, controller 530 can be further configured to determine a change in an orientation value of the interference fringe pattern data and determine the correction to the measurement value based on the change in the orientation value. In yet another example, controller 530 can be further configured to determine a change in a wave vector of the interference fringe pattern data and determine the correction to the measurement value based on the change in the wave vector.

In some aspects, controller 530 can be further configured to generate wave vector deviation data based on the interference fringe pattern data. The wave vector can contain both the period and the orientation of the interference pattern: the magnitude of the wave vector can be inversely proportional to the period; and the “angle” of the wave vector can be equivalent to the orientation of the fringes. In some aspects, controller 530 can be further configured to: (i) determine a first change in a periodicity value of the interference fringe pattern data based on the wave vector deviation data; (ii) determine a second change in an orientation value of the interference fringe pattern data based on the wave vector deviation data; and (iii) determine the correction to the measurement value based on the first change in the periodicity value and the second change in the orientation value.

In some aspects, the region of the surface of substrate 520 can include an alignment mark, and the interference fringe pattern data can correspond to a portion of the alignment mark. In such aspects, controller 530 can be further configured to determine the wave vector, period, orientation, or a combination thereof locally (e.g., independently for small parts of the mark) rather than globally over the whole alignment mark.

In some aspects, controller 530 can be further configured to generate a spatial map of a parameter based on the interference fringe pattern data and determine the correction to the measurement value based on the spatial map. In some aspects, controller 530 can be further configured to generate spatial maps of wave vector, period, orientation, or any other suitable parameter over the alignment mark. In some aspects, controller 530 can be further configured to generate a position map indicative of the local phase of the interference fringe pattern. In some aspects, the position map may contain information similar, but not identical, to a wave vector map. In some aspects, controller 530 can be further configured to use these spatial maps to determine corrections to measurement values (e.g., including spatially higher order terms).

In some aspects, the correction can include a correction to an overlay error of an overlay sensor, controller 530 can be further configured to determine the overlay error using interference patterns on cameras, such as by using cDBO, rAIM, digital holographic microscopy, or other suitable techniques. Additionally or alternatively, controller 530 can be further configured to determine the overlay error by combining a first set of measurements of intensity imbalance between positive and negative diffraction orders with a second set of measurements that contain an interference pattern. The intensity imbalance and the interference patterns can be measured, for example, in a single tool or in separate tools.

In some aspects, the technique of using properties of an interference pattern to correct the aligned position or overlay can be more general than the positive and negative first diffraction orders. For example, there can be some flexibility and variation in how the signal interference pattern is formed (e.g., by imaging device 528, controller 530) from combining: the zeroth, first, second, third, etc. diffraction orders; the positive and/or negative diffraction orders; partially clipped orders; and so forth.

In one illustrative and non-limiting example embodiment, measurement signal 529 can be indicative of a difference between positive first order diffraction 522 and negative first order diffraction 523. For example, the difference between positive first order diffraction 522 and negative first order diffraction 523 can include a phase difference between positive first order diffraction 522 and negative first order diffraction 523, the region can include an alignment mark, and controller 530 can be further configured to determine a correction to an alignment measurement of an alignment sensor based on the change in the periodicity value of the interference fringe pattern data. Continuing this example, in some aspects, controller 530 can be configured to decompose the observables on the camera into a set of reduced-dimensionality basis functions, modes, or mark shapes. These observables can result from mark variations combined with a sensor contribution (e.g., aberrations). Since the sensor may be assumed to be constant, each observed mark shape, or reduced-dimensionality basis function or modes, can correspond to a mark variation (e.g., mode). In some aspects, controller 530 can be configured to determine the correction to the alignment measurement further based on the set of reduced-dimensionality basis functions, modes, or mark shapes. In another example, the difference between positive first order diffraction 522 and negative first order diffraction 523 can include an intensity difference between positive first order diffraction 522 and negative first order diffraction 523, and controller 530 can be further configured to determine a correction to an overlay error of an overlay sensor based on the change in the periodicity value of the interference fringe pattern data.

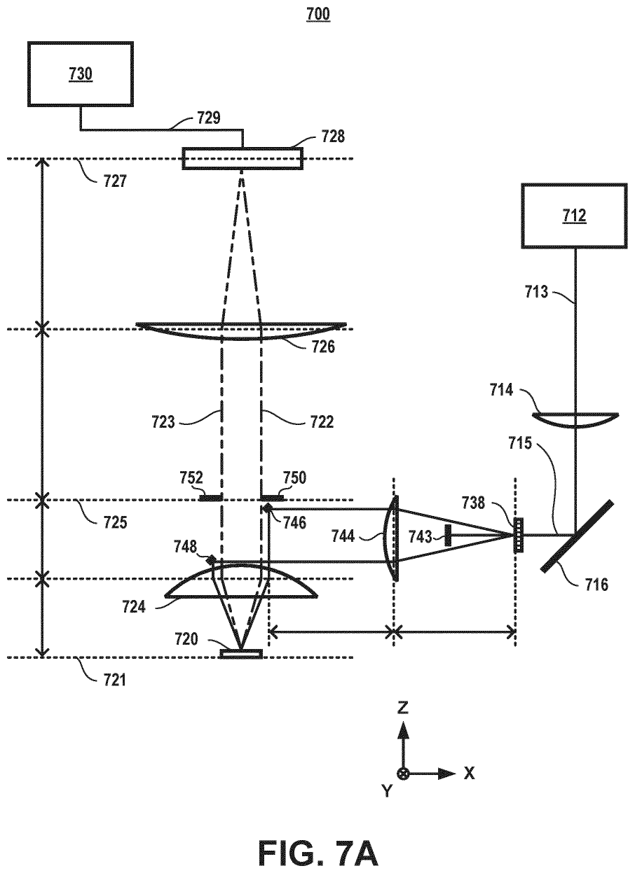

FIG. 6 is a schematic illustration showing example visualizations 600 of a measurement signal captured when conjugate X-diffracted orders are parallel to the X-axis, such as measurement signal 529 shown in FIG. 5, according to some aspects of the present disclosure. As shown in FIG. 6, example visualizations 600 can include a camera image 602 (e.g., captured by imaging device 528) having a first measurement 622 of positive first order diffraction 522 and a second measurement 623 of negative first order diffraction 523.

As further shown in FIG. 6, first measurement 622 and second measurement 623 can interfere to produce interference fringe pattern data 629. Interference fringe pattern data 629 indicates a change in periodicity, where a magnitude of the wave vector k increases and the vector is parallel to the X-axis. A controller (e.g., controller 530) can use interference fringe pattern data 629 to determine a change in the period of the interference fringe pattern on the field camera (e.g., on imaging device 528 at image plane 527, instead of an observable in pupil plane 525) to correct for measurement errors resulting from the coupled effects of a wide distribution of angles of incidence, sensor aberration, and stack thickness variation, or to correct for TIS. For example, the controller can be configured to correct an initial or raw alignment position measurement by solving the equation “Aligned_position_corrected=aligned_position_raw+correction_coefficient*observable_on_field_camera,” where the parameter “observable_on_field_camera” can be indicative of, for example, the change in the period of the fringe pattern.

FIGS. 7A and 7B are schematic illustrations showing side views of a metrology system 700 according to some aspects of the present disclosure. In some aspects, the metrology system 700, or any portion thereof, can be implemented using any of the structures, components, features, or techniques described with reference to the metrology system 400 described with reference to FIG. 4; the metrology system 500 described with reference to FIG. 5; the example computing system 1200 described with reference to FIG. 12; any of the systems, structures, components, features, or techniques described in European Patent Application No. 20170482.2, filed Apr. 20, 2020, and titled “ALIGNMENT METHOD AND ASSOCIATED ALIGNMENT AND LITHOGRAPHIC APPARATUSES,” which is hereby incorporated by reference in its entirety; any other suitable structure, component, feature, or technique; any portion thereof; or any combination thereof.

As shown in FIG. 7A, metrology system 700 can include an illumination system 712 (e.g., a light source) configured to generate a radiation beam 713 and direct radiation beam 713 toward a region of a surface of a substrate 720 that includes, in some aspects, a plurality of alignment marks. For example, metrology system 700 can further include a lens 714, a reflector 716 (e.g., a fold mirror), a reference grating 738, a radiation stop 743, a lens 744, a reflector 746, and a reflector 748. Illumination system 712 can transmit radiation beam 713 through lens 714 toward reflector 716. Reflector 716 can receive radiation beam 713 and direct the received radiation toward reference grating 738 as radiation beam 715.

FIG. 7B illustrates a portion of metrology system 700 in greater detail. As shown in FIG. 7B, radiation diffracted from reference grating 738 can include zeroth order diffraction 740, positive first order diffraction 741, and negative first order diffraction 742. Zeroth order diffraction 740 can propagate towards radiation stop 743. Positive first order diffraction 741 can propagate through lens 744 to reflector 746. Negative first order diffraction 742 can propagate through lens 744 to reflector 748. Reflector 746 can receive positive first order diffraction 741 and direct the received radiation toward substrate 720 as radiation beam 747. Reflector 748 can receive negative first order diffraction 742 and direct the received radiation toward substrate 720 as radiation beam 749.

In some aspects, radiation diffracted from the region of the surface of substrate 720 in response to an illumination of the region by radiation beam 747 can include positive first order diffraction 722. Positive first order diffraction 722 can propagate through a lens 724 (e.g., an objective lens), a radiation stop 750, and a lens 726 to an imaging device 728 (e.g., a camera) included in a detection system.

In some aspects, radiation diffracted from the region of the surface of substrate 720 in response to an illumination of the region by radiation beam 749 can include negative first order diffraction 723. Negative first order diffraction 723 can propagate through lens 724, a radiation stop 752, and lens 726 to imaging device 728.

Substrate 720 can be disposed at an object plane 721, imaging device 728 can be disposed at an image plane 727, and a pupil plane 725 can be disposed between object plane 721 and image plane 727.

The detection system can be configured to measure (e.g., by imaging device 728 at image plane 727) an interference between the radiation diffracted from the region of the surface of substrate 720 in response to the illumination of the region by radiation beam 747 and radiation beam 749 and generate a measurement signal 729 that includes interference fringe pattern data indicative of the measured interference.

Metrology system 700 can further include a controller 730 configured to receive measurement signal 729 from imaging device 728 and determine a correction to a measurement value based on the interference fringe pattern data included in measurement signal 729. The correction can include, for example, a correction to an alignment measurement of an alignment sensor, a correction to an overlay error of an overlay sensor, any other suitable correction or modification, and any combination thereof. In some aspects, controller 730 can be configured to utilize the correction to increase intra-field wafer alignment, perform wafer edge correction, reduce scribe lane width, reduce process impact on a surrounding product, any other suitable improvement, or any combination thereof.

In some aspects, controller 730 can be configured to correct for symmetric variations (e.g., layer thickness variations) in the alignment marks. Additionally or alternatively, in some aspects, controller 730 can be configured to correct for asymmetric variations (e.g., grating asymmetry, spatially varying layer thickness variation, spatially varying linewidth, surrounding structure variation, etc.) in the alignment marks and/or aberration profiles in the sensor. In some aspects, the disclosed embodiments may correct for symmetric and/or asymmetric variations in the alignment marks in cases where a symmetric variation in the mark combined with an asymmetric variation in the sensor leads to an alignment error.

In some aspects, controller 730 can be configured to determine a measurement value or correction therefor using at least one observable (e.g., periodicity, orientation, higher order terms) derived from the interference pattern measurement and at least one corresponding sensor or correction term relating to sensor optics used to perform said measurement. For example, controller 730 can be further configured to determine a change in a periodicity value of the interference fringe pattern data and determine the correction to the measurement value based on the change in the periodicity value. In another example, controller 730 can be further configured to determine a change in an orientation value of the interference fringe pattern data and determine the correction to the measurement value based on the change in the orientation value. In yet another example, controller 730 can be further configured to determine a change in a wave vector of the interference fringe pattern data and determine the correction to the measurement value based on the change in the wave vector.

In some aspects, controller 730 can be further configured to generate wave vector deviation data based on the interference fringe pattern data. The wave vector can contain both the period and the orientation of the interference pattern: the magnitude of the wave vector can be inversely proportional to the period; and the “angle” of the wave vector can be equivalent to the orientation of the fringes. In some aspects, controller 730 can be further configured to: (i) determine a first change in a periodicity value of the interference fringe pattern data based on the wave vector deviation data; (ii) determine a second change in an orientation value of the interference fringe pattern data based on the wave vector deviation data; and (iii) determine the correction to the measurement value based on the first change in the periodicity value and the second change in the orientation value.

In some aspects, the region of the surface of substrate 720 can include an alignment mark, and the interference fringe pattern data can correspond to a portion of the alignment mark. In such aspects, controller 730 can be further configured to determine the wave vector, period, orientation, or a combination thereof locally (e.g., independently for small parts of the mark) rather than globally over the whole alignment mark.

In some aspects, controller 730 can be further configured to generate a spatial map of a parameter based on the interference fringe pattern data and determine the correction to the measurement value based on the spatial map. In some aspects, controller 730 can be further configured to generate spatial maps of wave vector, period, orientation, or any other suitable parameter over the alignment mark. In some aspects, controller 730 can be further configured to generate a position map indicative of the local phase of the interference fringe pattern. In some aspects, the position map may contain information similar, but not identical, to a wave vector map. In some aspects, controller 730 can be further configured to use these spatial maps to determine corrections to measurement values (e.g., including higher order terms).

In some aspects, the correction can include a correction to an overlay error of an overlay sensor, controller 730 can be further configured to determine the overlay error using interference patterns on cameras, such as by using cDBO, digital holographic microscopy, or other suitable techniques. Additionally or alternatively, controller 730 can be further configured to determine the overlay error by combining a first set of measurements of intensity imbalance between positive and negative diffraction orders with a second set of measurements that contain an interference pattern. The intensity imbalance and the interference patterns can be measured, for example, in a single tool or in separate tools.

In some aspects, the technique of using properties of an interference pattern to correct the aligned position or overlay can be more general than the positive and negative first diffraction orders. For example, there can be some flexibility and variation in how the signal interference pattern is formed (e.g., by imaging device 728, controller 730) from combining: the zeroth, first, second, third, etc. diffraction orders; the positive and/or negative diffraction orders; partially clipped orders; and so forth.

In one illustrative and non-limiting example embodiment, measurement signal 729 can be indicative of a difference between positive first order diffraction 722 and negative first order diffraction 723. For example, the difference between positive first order diffraction 722 and negative first order diffraction 723 can include a phase difference between positive first order diffraction 722 and negative first order diffraction 723, the region can include an alignment mark, and controller 730 can be further configured to determine a correction to an alignment measurement of an alignment sensor based on the change in the periodicity value of the interference fringe pattern data. Continuing this example, in some aspects, controller 730 can be configured to determine the correction to the alignment measurement further based on a set of reduced-dimensionality basis functions representing different modes of alignment mark asymmetry. In another example, the difference between positive first order diffraction 722 and negative first order diffraction 723 can include an intensity difference between positive first order diffraction 722 and negative first order diffraction 723, and controller 730 can be further configured to determine a correction to an overlay error of an overlay sensor based on the change in the periodicity value of the interference fringe pattern data.

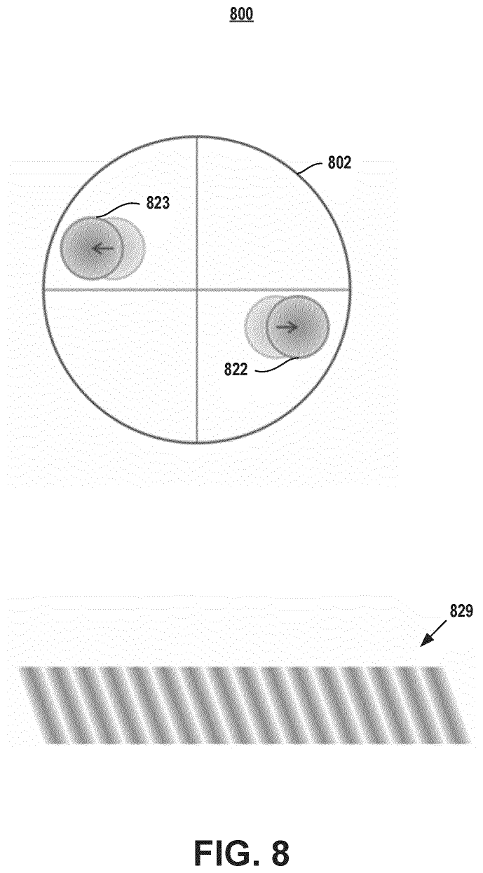

FIG. 8 is a schematic illustration showing example visualizations 800 of a measurement signal, such as measurement signal 729 shown in FIG. 7A, captured when conjugate X-diffracted orders are not parallel to the X-axis according to some aspects of the present disclosure. As shown in FIG. 8, example visualizations 800 can include a camera image 802 (e.g., captured by imaging device 728) having a first measurement 822 of positive first order diffraction 722 and a second measurement 823 of negative first order diffraction 723.

As further shown in FIG. 8, first measurement 822 and second measurement 823 can interfere to produce interference fringe pattern data 829. Interference fringe pattern data 829 indicates a change in periodicity and orientation, where a magnitude of the wave vector k increases and the vector rotates to become more parallel to the X-axis. A controller (e.g., controller 730) can use interference fringe pattern data 829 to determine a change in the period and/or orientation of the fringe pattern on the field camera (e.g., on imaging device 728 at image plane 727, instead of an observable in pupil plane 725) to correct for the measurement errors resulting from the coupled effects of a wide distribution of angles of incidence, sensor aberration, and stack thickness variation, or to correct for TIS. For example, the controller can be configured to correct an initial or raw alignment position measurement by solving the equation “Aligned_position_corrected=aligned_position_raw+correction_coefficient*observable_on_field_camera,”where the parameter “observable_on_field_camera” can be indicative of, for example, the change in the period and/or orientation of the fringe pattern.

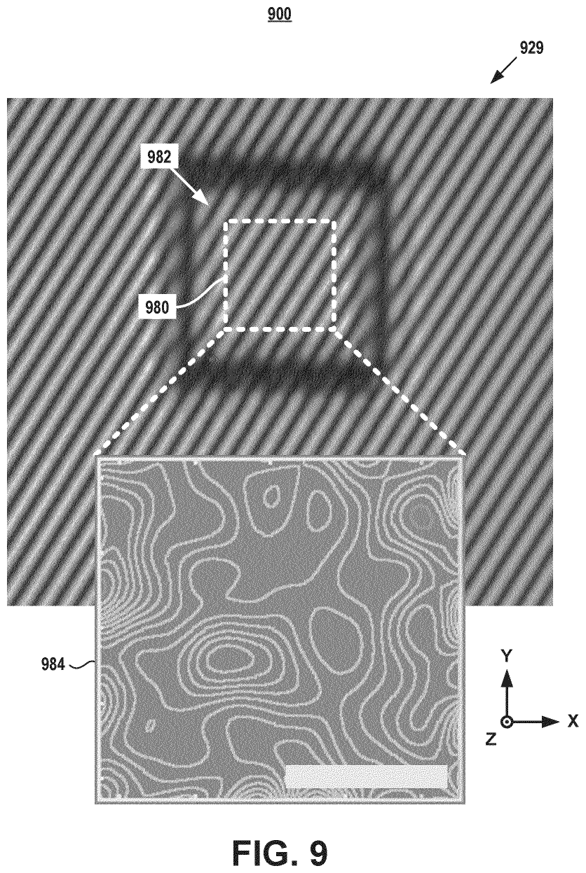

FIG. 9 is a schematic illustration showing example visualizations 900 of a measurement signal, such as measurement signal 729 shown in FIG. 7A, captured when conjugate X-diffracted orders are not parallel to the X-axis according to some aspects of the present disclosure. As shown in FIG. 9, example visualizations 900 can include interference fringe pattern data 929 resulting from an interference between positive first order diffraction 722 and negative first order diffraction 723. Interference fringe pattern data 929 indicates a change in periodicity and orientation, where a magnitude of the wave vector k increases and the vector rotates to become more parallel to the X-axis.

In some aspects, a controller (e.g., controller 730) can be configured to generate a position map 984 for a region 980 of an alignment mark 982 included in interference fringe pattern data 929. Position map 984 can be indicative of the local phase of the interference fringe pattern data 929 in region 980. For example, the controller can be configured to locally fit the phase intensity of interference fringe pattern data 929 and plot that fit on position map 984. In some aspects, the controller can detect a spatial variation in the position map 984 (e.g., in the form of a spatial gradient) over the length scale of the alignment mark 982 as a result of, for instance, layer thickness change. In some aspects, wave vector k variations can show up as deviations in position map 984, and the observable determined by the controller can be the change in the wave vector k seen in position map 984. In some aspects, the controller can be further configured to use position map 984 to determine corrections to measurement values (e.g., including higher order terms).

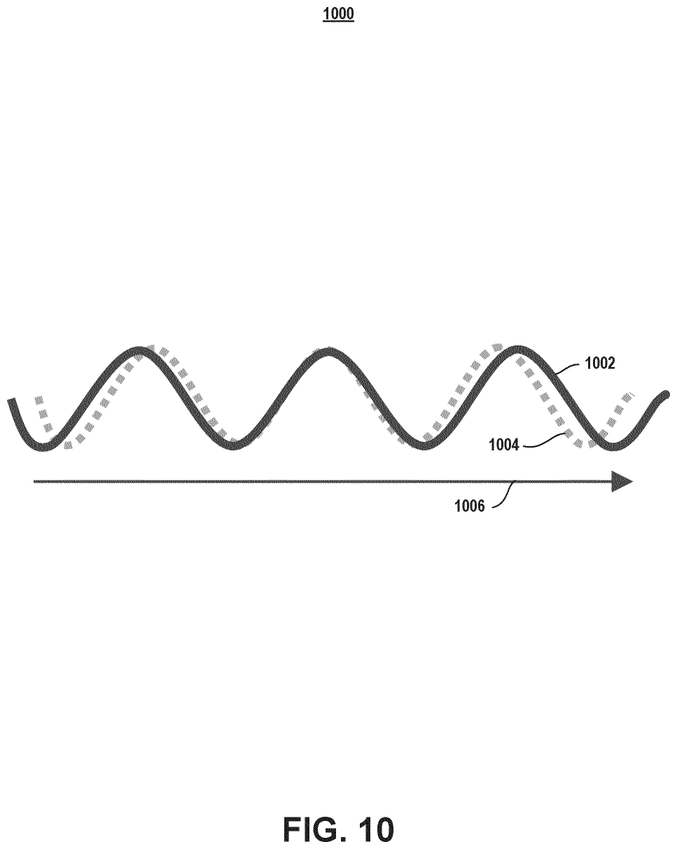

FIG. 10 is a schematic illustration showing an example graphical representation 1000 of a measurement signal, such as measurement signal 729 shown in FIG. 7A, according to some aspects of the present disclosure. As shown in FIG. 10, example graphical representation 1000 can include a one-dimensional slice of a camera image (e.g., captured by imaging device 728), or a one-dimensional signal obtained by processing the camera image, where measurement signal 1002 is indicative of nominal layer thickness, measurement signal 1004 is indicative of a different layer thickness resulting from a layer thickness variation, and axis 1006 corresponds to the pixel position of the camera. In some aspects, the fringe period change resulting from the layer thickness variation can be visible on the camera (e.g., on imaging device 728).

### Example Processes for Correcting an Alignment Measurement or Overlay Error

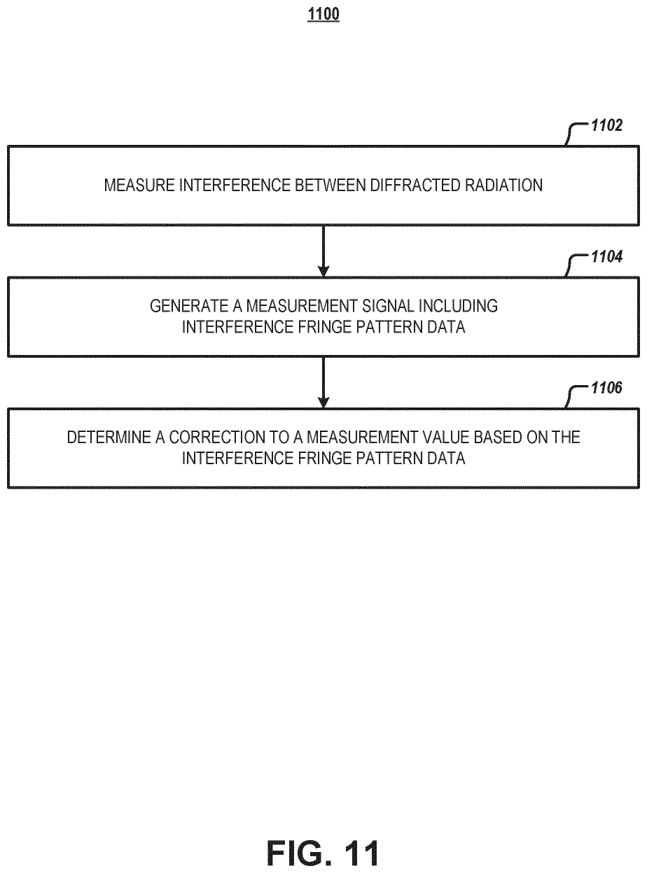

FIG. 11 is an example method 1100 for correcting an alignment measurement or overlay error according to some aspects of the present disclosure or portion(s) thereof. The operations described with reference to example method 1100 can be performed by, or according to, any of the systems, apparatuses, components, techniques, or combinations thereof described herein, such as those described with reference to FIGS. 1-10 above and FIG. 12 below.

At operation 1102, the method can include measuring, by an imaging device (e.g., detector 428; imaging device 528, 728) and at an image plane (e.g., image plane 527, 727) of the imaging device, an interference between radiation (e.g., radiation beam 417; positive first order diffraction 522 and negative first order diffraction 523; positive first order diffraction 722 and negative first order diffraction 723) diffracted from a region of a surface of a substrate (e.g., substrate 420, 520, 720) in response to an illumination of the region by a radiation beam (e.g., radiation beam 415, 517, 747, 749). In some aspects, the measuring of the interference can be accomplished using suitable optical, electrical, mechanical, or other methods and include measuring the interference in accordance with any aspect or combination of aspects described with reference to FIGS. 1-10 above and FIG. 12 below.

At operation 1104, the method can include generating, by a controller (e.g., controller 430, 530, 730), a measurement signal (e.g., measurement signal 429, 529, 729) comprising interference fringe pattern data (e.g., interference fringe pattern data 629, 829, 929) indicative of the interference measured at operation 1102. In some aspects, the generating of the measurement signal can be accomplished using suitable optical, electrical, mechanical, or other methods and include generating the measurement signal in accordance with any aspect or combination of aspects described with reference to FIGS. 1-10 above and FIG. 12 below.

At operation 1106, the method can include determining, by the controller, a correction to a measurement value based on the interference fringe pattern data.

In some aspects, the correction can include a “correction_coefficient” parameter that has been calibrated (i) with a rotated wafer measurement, and/or (ii) with AEI metrology and SEM feedback, and/or (iii) with D4C simulated data, which may be combined with modeled or measured sensor aberration data, and/or (iv) by comparing overlay data measured on multiple nearby marks with, for example, different pitches and/or subsegmentations, and/or (v) by comparing through-color data (e.g., when many colors are measured in a calibration phase and fewer colors are measured in a high-volume phase to increase throughput). Optionally, the method can include calibrating, by the controller, the “correction_coefficient” parameter in various ways, such as by measuring the optical aberration profile of the sensor or using ADI, AEI, or SEM feedback data, based on D4C simulated data, by comparing alignment data measured on multiple nearby marks with different pitches and/or subsegmentations, and/or by comparing through-color data (e.g., assuming smoothness of the optical aberration profile).

In one example, at operation 1106, the method can include determining, by the controller, a correction to an alignment measurement of an alignment sensor based on the interference fringe pattern data. In another example, at operation 1106, the method can include determining, by the controller, a correction to an overlay error of an overlay sensor based on the interference fringe pattern data. Optionally, the method can further include determining, by the controller, a change in a parameter of the interference fringe pattern data and then determining, by the controller, the correction to the measurement value based on the change in the parameter of the interference fringe pattern data. The parameter can be selected from the group consisting of, for example, a periodicity value of the interference fringe pattern data, an orientation value of the interference fringe pattern data, a wave vector of the interference fringe pattern data, any other suitable parameter, and any combination thereof. In some aspects, the determining of the correction can be accomplished using suitable optical, electrical, mechanical, or other methods and include determining the correction in accordance with any aspect or combination of aspects described with reference to FIGS. 1-10 above and FIG. 12 below.

In some aspects, the observables on the camera can correlate to layer thickness. These observables can be sent to a higher-level fab control and used to track process changes or process drift. For example, when the observables go out-of-spec, wafers can be sent for additional metrology or rework. Alternatively, the observables can be used as a flag for optimizing or re-optimizing certain processing steps in the fab or even as direct input parameters for optimizing or re-optimizing processing steps such as deposition, etch, chemical mechanical polishing (CMP), and other suitable steps. In some aspects, the observables can be used to optimize or re-optimize the lithography step during which the alignment mark was exposed.

### Example Computing System

Aspects of the disclosure can be implemented in hardware, firmware, software, or any combination thereof. Aspects of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions, and combinations thereof can be described herein as performing certain actions. However, it should be appreciated that such descriptions are merely for convenience and that such actions in fact result from computing devices, processors, controllers, or other devices executing the firmware, software, routines, instructions, or combinations thereof and, in doing so, causing actuators or other devices (e.g., servo motors, robotic devices) to interact with the physical world.

Various aspects can be implemented, for example, using one or more computing systems, such as example computing system 1200 shown in FIG. 12. Example computing system 1200 can be a specialized computer capable of performing the functions described herein such as: the example metrology system 400 described with reference to FIG. 4; the example metrology system 500 described with reference to FIG. 5; the example metrology system 700 described with reference to FIG. 7; any other suitable system, sub-system, or component; or any combination thereof. Example computing system 1200 can include one or more processors (also called central processing units, or CPUs), such as a processor 1204. Processor 1204 is connected to a communication infrastructure 1206 (e.g., a bus). Example computing system 1200 can also include user input/output device(s) 1203, such as monitors, keyboards, pointing devices, etc., that communicate with communication infrastructure 1206 through user input/output interface(s) 1202. Example computing system 1200 can also include a main memory 1208 (e.g., one or more primary storage devices), such as random access memory (RAM). Main memory 1208 can include one or more levels of cache. Main memory 1208 has stored therein control logic (e.g., computer software) and/or data.

Example computing system 1200 can also include a secondary memory 1210 (e.g., one or more secondary storage devices). Secondary memory 1210 can include, for example, a hard disk drive 1212 and/or a removable storage drive 1214. Removable storage drive 1214 can be a floppy disk drive, a magnetic tape drive, a compact disk drive, an optical storage device, tape backup device, and/or any other storage device/drive.

Removable storage drive 1214 can interact with a removable storage unit 1218. Removable storage unit 1218 includes a computer usable or readable storage device having stored thereon computer software (control logic) and/or data. Removable storage unit 1218 can be a floppy disk, magnetic tape, compact disk, DVD, optical storage disk, and/or any other computer data storage device. Removable storage drive 1214 reads from and/or writes to removable storage unit 1218.

According to some aspects, secondary memory 1210 can include other means, instrumentalities or other approaches for allowing computer programs and/or other instructions and/or data to be accessed by example computing system 1200. Such means, instrumentalities or other approaches can include, for example, a removable storage unit 1222 and an interface 1220. Examples of the removable storage unit 1222 and the interface 1220 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Example computing system 1200 can further include a communications interface 1224 (e.g., one or more network interfaces). Communications interface 1224 enables example computing system 1200 to communicate and interact with any combination of remote devices, remote networks, remote entities, etc. (individually and collectively referred to as remote devices 1228). For example, communications interface 1224 can allow example computing system 1200 to communicate with remote devices 1228 over communications path 1226, which can be wired and/or wireless, and which can include any combination of LANs, WANs, the Internet, etc. Control logic, data, or both can be transmitted to and from example computing system 1200 via communications path 1226.

The operations in the preceding aspects of the present disclosure can be implemented in a wide variety of configurations and architectures. Therefore, some or all of the operations in the preceding aspects can be performed in hardware, in software or both. In some aspects, a tangible, non-transitory apparatus or article of manufacture includes a tangible, non-transitory computer useable or readable medium having control logic (software) stored thereon is also referred to herein as a computer program product or program storage device. This includes, but is not limited to, example computing system 1200, main memory 1208, secondary memory 1210 and removable storage units 1218 and 1222, as well as tangible articles of manufacture embodying any combination of the foregoing. Such control logic, when executed by one or more data processing devices (such as example computing system 1200), causes such data processing devices to operate as described herein.

Based on the teachings contained in this disclosure, it will be apparent to persons skilled in the relevant art(s) how to make and use aspects of the disclosure using data processing devices, computer systems and/or computer architectures other than that shown in FIG. 12. In particular, aspects of the disclosure can operate with software, hardware, and/or operating system implementations other than those described herein.

The embodiments may further be described using the following clauses:
1. A metrology system, comprising:
   an illumination system configured to:
      generate a radiation beam, and
      direct the radiation beam toward a region of a surface of a substrate;
   a detection system configured to:
      measure an observable from the region in response to an illumination of the region by the radiation beam, and
      generate a measurement signal indicative of the measured observable; and
   a controller configured to:
      determine a correction to a measurement value based on the measurement signal.
2. The metrology system of clause 1, wherein:
   the detection system is further configured to:
      measure an interference between radiation diffracted from the region in response to the illumination of the region by the radiation beam, and
      generate the measurement signal comprising interference fringe pattern data indicative of the measured interference; and
   the controller is further configured to:
      determine the correction to the measurement value based on the interference fringe pattern data.
3. The metrology system of clause 2, wherein the controller is further configured to:
   determine a change in a periodicity value of the interference fringe pattern data; and
   determine the correction to the measurement value based on the change in the periodicity value.
4. The metrology system of clause 2, wherein the controller is further configured to:
   determine a change in an orientation value of the interference fringe pattern data; and
   determine the correction to the measurement value based on the change in the orientation value.
5. The metrology system of clause 2, wherein the controller is further configured to:
   determine a change in a wave vector of the interference fringe pattern data; and
   determine the correction to the measurement value based on the change in the wave vector.
6. The metrology system of clause 2, wherein:
   the region comprises an alignment mark; and
   the interference fringe pattern data corresponds to a portion of the alignment mark.
7. The metrology system of clause 2, wherein the controller is further configured to:
   generate a spatial map of a parameter based on the interference fringe pattern data; and
   determine the correction to the measurement value based on the spatial map.
8. The metrology system of clause 1, wherein the correction comprises:
   a first correction to an alignment measurement of an alignment sensor; or
   a second correction to an overlay error of an overlay sensor.
9. The metrology system of clause 8, wherein the controller is further configured to optimize a lithography step during which an alignment mark was exposed based on the observable.
10. A lithographic apparatus, comprising:
   a radiation source configured to illuminate a pattern of a patterning device;
   a projection system configured to project an image of the pattern onto a target portion of a substrate; and
   a metrology system comprising:
      an illumination system configured to:
         generate a radiation beam, and
         direct the radiation beam toward a region of a surface of a substrate;
      a detection system configured to:
         measure an observable from the region in response to an illumination of the region by the radiation beam, and
         generate a measurement signal indicative of the measured observable; and
      a controller configured to:
         determine a correction to a measurement value based on the measurement signal.
11. The lithographic apparatus of clause 10, wherein:
   the detection system is further configured to:
      measure an interference between radiation diffracted from the region in response to the illumination of the region by the radiation beam, and
      generate the measurement signal comprising interference fringe pattern data indicative of the measured interference; and
the controller is further configured to:
   determine the correction to the measurement value based on the interference fringe pattern data.
12. The lithographic apparatus of clause 11, wherein the controller is further configured to:
   determine a change in a periodicity value of the interference fringe pattern data; and
   determine the correction to the measurement value based on the change in the periodicity value.
13. The lithographic apparatus of clause 11, wherein the controller is further configured to:
   determine a change in an orientation value of the interference fringe pattern data; and
   determine the correction to the measurement value based on the change in the orientation value.
14. The lithographic apparatus of clause 11, wherein the controller is further configured to:
   determine a change in a wave vector of the interference fringe pattern data; and
   determine the correction to the measurement value based on the change in the wave vector.
15. The lithographic apparatus of clause 10, wherein the correction comprises:
   a first correction to an alignment measurement of an alignment sensor; or
   a second correction to an overlay error of an overlay sensor.
16. A method, comprising:
   measuring, by an imaging device and at an image plane of the imaging device, an observable from a region of a surface in response to an illumination of the region by a radiation beam;
   generating, by a controller, a measurement signal indicative of the measured observable; and
   determining, by the controller, a correction to a measurement value based on the measurement signal.
17. The method of clause 16, wherein the method further comprises:
   measuring, by the imaging device and at the image plane of the imaging device, an interference between radiation diffracted from the region in response to the illumination of the region by the radiation beam;
   generating, by the controller, the measurement signal comprising interference fringe pattern data indicative of the measured interference; and
   determining, by the controller, the correction to the measurement value based on the interference fringe pattern data.
18. The method of clause 17, wherein the method further comprises:
   determining, by the controller, a change in a parameter of the interference fringe pattern data, wherein the parameter is selected from the group consisting of a periodicity value of the interference fringe pattern data, an orientation value of the interference fringe pattern data, a wave vector of the interference fringe pattern data, and a combination thereof; and
   determining, by the controller, the correction to the measurement value based on the change in the parameter of the interference fringe pattern data.
19. The method of clause 17, wherein the method further comprises determining, by the controller, a correction to an alignment measurement of an alignment sensor based on the interference fringe pattern data.
20. The method of clause 17, wherein the method further comprises determining, by the controller, a correction to an overlay error of an overlay sensor based on the interference fringe pattern data.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

1-15. (canceled)

16. A metrology system, comprising:
an illumination system configured to:
generate a radiation beam, and
direct the radiation beam toward a region of a surface of a substrate;
a detection system configured to:
measure an observable from the region in response to an illumination of the region by the radiation beam, and
generate a measurement signal indicative of the measured observable; and
a controller configured to determine a correction to a measurement value based on the measurement signal.

17. The metrology system of claim 16, wherein:
the detection system is further configured to:
measure an interference between radiation diffracted from the region in response to the illumination of the region by the radiation beam, and
generate the measurement signal comprising interference fringe pattern data indicative of the measured interference; and
the controller is further configured to determine the correction to the measurement value based on the interference fringe pattern data.

18. The metrology system of claim 17, wherein the controller is further configured to:
determine a change in a periodicity value of the interference fringe pattern data; and
determine the correction to the measurement value based on the change in the periodicity value.

19. The metrology system of claim 17, wherein the controller is further configured to:
determine a change in an orientation value of the interference fringe pattern data; and
determine the correction to the measurement value based on the change in the orientation value.

20. The metrology system of claim 17, wherein the controller is further configured to:
determine a change in a wave vector of the interference fringe pattern data; and
determine the correction to the measurement value based on the change in the wave vector.

21. The metrology system of claim 17, wherein:
the region comprises an alignment mark; and
the interference fringe pattern data corresponds to a portion of the alignment mark.

22. The metrology system of claim 17, wherein the controller is further configured to:
generate a spatial map of a parameter based on the interference fringe pattern data; and
determine the correction to the measurement value based on the spatial map.

23. The metrology system of claim 16, wherein the correction comprises:
a first correction to an alignment measurement of an alignment sensor; or
a second correction to an overlay error of an overlay sensor.

24. The metrology system of claim 23, wherein the controller is further configured to optimize a lithography step during an exposure of an alignment mark based on the observable.

25. A lithographic apparatus, comprising:
a radiation source configured to illuminate a pattern of a patterning device;
a projection system configured to project an image of the pattern onto a target portion of a substrate; and
a metrology system comprising:
an illumination system configured to:
generate a radiation beam, and
direct the radiation beam toward a region of a surface of a substrate;
a detection system configured to measure an observable from the region in response to an illumination of the region by the radiation beam, and
generate a measurement signal indicative of the measured observable; and
a controller configured to determine a correction to a measurement value based on the measurement signal.

26. The lithographic apparatus of claim 25, wherein:
the detection system is further configured to:
measure an interference between radiation diffracted from the region in response to the illumination of the region by the radiation beam, and
generate the measurement signal comprising interference fringe pattern data indicative of the measured interference; and
the controller is further configured to determine the correction to the measurement value based on the interference fringe pattern data.

27. The lithographic apparatus of claim 26, wherein the controller is further configured to:
determine a change in a periodicity value of the interference fringe pattern data; and
determine the correction to the measurement value based on the change in the periodicity value.

28. The lithographic apparatus of claim 26, wherein the controller is further configured to:
determine a change in an orientation value of the interference fringe pattern data; and
determine the correction to the measurement value based on the change in the orientation value.

29. The lithographic apparatus of claim 26, wherein the controller is further configured to:
determine a change in a wave vector of the interference fringe pattern data; and
determine the correction to the measurement value based on the change in the wave vector.

30. The lithographic apparatus of claim 25, wherein the correction comprises:
a first correction to an alignment measurement of an alignment sensor; or
a second correction to an overlay error of an overlay sensor.

31. A method, comprising:
measuring, by an imaging device and at an image plane of the imaging device, an observable from a region of a surface in response to an illumination of the region by a radiation beam;
generating, by a controller, a measurement signal indicative of the measured observable; and
determining, by the controller, a correction to a measurement value based on the measurement signal.

32. The method of clause 31, wherein the method further comprises:
measuring, by the imaging device and at the image plane of the imaging device, an interference between radiation diffracted from the region in response to the illumination of the region by the radiation beam;
generating, by the controller, the measurement signal comprising interference fringe pattern data indicative of the measured interference; and
determining, by the controller, the correction to the measurement value based on the interference fringe pattern data.

33. The method of clause 32, wherein the method further comprises:
determining, by the controller, a change in a parameter of the interference fringe pattern data, wherein the parameter is selected from the group consisting of a periodicity value of the interference fringe pattern data, an orientation value of the interference fringe pattern data, a wave vector of the interference fringe pattern data, and a combination thereof; and
determining, by the controller, the correction to the measurement value based on the change in the parameter of the interference fringe pattern data.

34. The method of clause 32, wherein the method further comprises determining, by the controller, a correction to an alignment measurement of an alignment sensor based on the interference fringe pattern data.

35. The method of clause 32, wherein the method further comprises determining, by the controller, a correction to an overlay error of an overlay sensor based on the interference fringe pattern data.
